(19) United States
(12) Patent Application Publication
(10) Pub. No.: US 2026/0259630 A1
(43) Pub. Date: Sep. 3, 2026

(54) TOUCH DEVICE OF DISPLAY AND METHOD OF CONTROLLING THE SAME

(71) Applicant: LX Semicon Co.,Ltd., Daejeon (KR)

(72) Inventors: Chin Wan LEE, Daejeon (KR); Jae Hwan LEE, Daejeon (KR)

(73) Assignee: LX Semicon Co.,Ltd., Daejeon (KR)

(21) Appl. No.: 19/552,504

(22) Filed: Feb. 27, 2026

(30) Foreign Application Priority Data
Feb. 28, 2025 (KR) 10-2025-0026660

(51) Int. Cl. G06F 3/041; G06F 3/044

(52) U.S. Cl. CPC G06F 3/04182; G06F 3/0412; G06F 3/04184; G06F 3/044

(57) ABSTRACT

Disclosed are a method and device for addressing an issue of degradation of a signal-to-noise ratio SNR of small touch sensor nodes located in an outer region of a circular display. Due to design characteristics of the circular display, sizes of touch sensors in the outer region are reduced, which leads to degradation of the SNR and causes imbalance in touch sensitivity. To address such an issue, provided is an SNR correction method including techniques such as grouping nodes based on sensor size and amplifying signals.

This application claims the benefit of Korean Patent Application No. 10-2025-0026660, filed on February 28, 2025, which is hereby incorporated by reference as if fully set forth herein.

### FIELD OF THE DISCLOSURE

The present disclosure relates to a touch device of a display and a method of controlling the same.

### DISCUSSION OF THE RELATED ART

A display device generally includes a touchscreen to detect user input, and capacitive sensing is widely used as an input detection method for touchscreens. A capacitive touch panel includes touch sensors, and when a touch input occurs, a touch controller detects a change in capacitance to recognize a touch event.

A typical capacitive touchscreen is designed based on a tetragonal (square or rectangular) display, and in such a structure, the size and arrangement of touch sensor nodes are uniformly maintained. However, in a circular display, a touch sensor size may be differently formed between a central region and an outer region of the display. In particular, touch sensor nodes disposed at an edge of the circular display become smaller, which may lead to a reduction in touch sensitivity.

To address these issues, there is a need to effectively improve an SNR (signal-to-noise ratio) of small sensor nodes so that stable touch sensitivity may be maintained even in an outer region of the circular display.

### SUMMARY OF THE DISCLOSURE

Accordingly, the present disclosure is directed to a touch device of a display and a method of controlling the same that substantially obviate one or more problems due to limitations and disadvantages of the related art.

An aspect of the present disclosure is to provide a touch device and a method of controlling the same that solve problems of non-uniformity of touch sensitivity and degradation of an SNR caused by differences in sizes of touch sensors in a display.

The technical problems to be solved by the present disclosure are not limited to the technical problems described above, and other technical problems not mentioned herein will be clearly understood by those having ordinary skill in the art to which the present disclosure pertains from the following description.

Additional advantages, objects, and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these objects and other advantages and in accordance with the purpose of the disclosure, as embodied and broadly described herein, a touch device of a display includes a plurality of touch sensor nodes configured to sense touch signals of a touch display panel, and a plurality of multiplexers (MUXs) configured to collect the touch signals sensed by the plurality of touch sensor nodes and to selectively output the touch signals, wherein the plurality of touch sensor nodes is classified into a plurality of node groups based on sizes of the touch sensor nodes, and the plurality of MUXs respectively correspond to the plurality of classified node groups to collect the touch signals and selectively output at least one touch signal among the touch sensor nodes in each node group.

In at least one embodiment of the present disclosure, the plurality of touch sensor nodes may include self-dot type touch sensors.

In at least one embodiment of the present disclosure, the plurality of node groups may include a first group having a first touch sensor node size, a second group having a second touch sensor node size larger than the first touch sensor node size, and a third group having a third touch sensor node size larger than the second touch sensor node size.

In at least one embodiment of the present disclosure, the touch device may further include a plurality of amplifiers respectively corresponding to the plurality of MUXs and configured to amplify a difference between the touch signals output from the plurality of MUXs and a touch driving voltage.

In at least one embodiment of the present disclosure, the touch device may further include a power unit configured to supply the touch driving voltage to the amplifiers.

In at least one embodiment of the present disclosure, the power unit may supply the touch driving voltage having a different voltage level for each of the plurality of node groups.

In at least one embodiment of the present disclosure, the touch device may further include a control unit configured to control the power unit to adjust the touch driving voltage.

In at least one embodiment of the present disclosure, the supplying the touch driving voltage having a different voltage level for each of the plurality of node groups may include supplying a first level voltage to the first group, supplying a second level voltage lower than the first level voltage to the second group, and supplying a third level voltage lower than the second level voltage to the third group.

In at least one embodiment of the present disclosure, in a power saving mode, the first level voltage and the second level voltage may be changed to the third level voltage.

In another aspect of the present disclosure, a method for controlling a touch device of a display includes sensing touch signals of a touch panel, and collecting and selectively outputting the sensed touch signals, wherein the sensing touch signals includes classifying the touch signals into a plurality of groups based on sizes of a plurality of touch sensor nodes and sensing the touch signals, and the collecting and selectively outputting the touch signals includes collecting the touch signals respectively corresponding to the plurality of classified node groups and selectively outputting at least one touch signal among the touch sensor nodes within each node group.

In at least one embodiment of the present disclosure, the plurality of node groups may include a first group having a first touch sensor node size, a second group having a second touch sensor node size larger than the first touch sensor node size, and a third group having a third touch sensor node size larger than the second touch sensor node size.

In at least one embodiment of the present disclosure, the method may further include amplifying a difference between the output touch signal and a touch driving voltage.

In at least one embodiment of the present disclosure, the method may further include supplying the touch driving voltage having a different voltage level for each of the plurality of node groups.

In at least one embodiment of the present disclosure, the supplying the touch driving voltage having a different voltage level for each of the plurality of node groups may include supplying a first level voltage to the first group, supplying a second level voltage lower than the first level voltage to the second group, and supplying a third level voltage lower than the second level voltage to the third group.

In at least one embodiment of the present disclosure, in a power saving mode, the first level voltage and the second level voltage may be changed to the third level voltage.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a diagram illustrating a configuration of a circular display touch device according to an embodiment of the present disclosure;

FIG. 2 is a timing diagram of a touch display driving device for a display period and a touch sensing period in one frame according to an embodiment of the present disclosure;

FIG. 3 is a diagram of a configuration in which touch sensor nodes are grouped based on sizes in a circular touch display panel according to an embodiment of the present disclosure;

FIG. 4 is a block diagram of a configuration in which touch sensor nodes are grouped based on sizes in the circular touch display panel according to an embodiment of the present disclosure;

FIG. 5 is a diagram illustrating a scenario of changing a touch mode by a host in the circular touch display panel according to an embodiment of the present disclosure;

FIG. 6 is a flowchart of controlling a power unit in a touch driving device of the circular touch display panel according to an embodiment of the present disclosure; and

FIG. 7 is a diagram illustrating a self-dot type touch sensor according to an embodiment of the present disclosure.

### DETAILED DESCRIPTION OF THE DISCLOSURE

The present disclosure may be variously modified and may have various embodiments, and specific embodiments will be illustrated in the drawings and described. However, this is not intended to limit the present disclosure to specific embodiments, and it should be understood that the present disclosure includes all modifications, equivalents, and substitutes falling within the spirit and technical scope of the present disclosure.

Suffixes such as "module" and "unit" used herein are used merely for nominal distinction between components, and should not be construed as implying that the components are physically or chemically divided or separated or that the components may be so divided or separated.

Terms including ordinal numbers such as "first" and "second" may be used to describe various components, but the components are not limited by these terms. These terms may be used only for nominal purposes to distinguish one component from another, and any order-related meaning is understood from the context of the description rather than from the terms.

The term "and/or" is used to include all possible combinations of a plurality of listed items. For example, "A and/or B" includes all three cases of "A", "B", and "A and B."

When a component is described as being "connected to" or "coupled to" another component, it should be understood that the component may be directly connected or coupled to the other component, or that one or more intervening components may be present therebetween.

The terminology used herein is for the purpose of describing particular embodiments only and is not intended to limit the present disclosure. Singular forms include plural forms as well, unless the context clearly indicates otherwise. In the present application, the terms "include" or "have" are intended to designate the presence of stated features, numbers, steps, operations, components, parts, or combinations thereof, but do not preclude the presence or addition of one or more other features, numbers, steps, operations, components, parts, or combinations thereof.

Unless otherwise defined, all terms used herein, including technical or scientific terms, have the same meaning as those generally understood by a person having ordinary skill in the art to which the present disclosure pertains. Terms defined in commonly used dictionaries are to be interpreted as having meanings consistent with meanings in the context of the relevant art, and are not to be interpreted in an idealized or overly formal sense unless expressly defined otherwise in the present application.

Further, terms such as unit, control unit, control device, or controller are merely terms widely used to name devices that control corresponding functions, and do not mean a generic functional unit. For example, devices referred to by these terms may include a communication device that communicates with other controllers or sensors to control the corresponding function, a computer-readable recording medium that stores an operating system, logic instructions, and input/output information, and one or more processors that perform determinations, calculations, and decisions necessary for controlling the assigned function.

Meanwhile, a processor may include semiconductor integrated circuits and/or electronic components that perform at least one of comparison, determination, calculation, or decision to achieve programmed functions. By way of example, the processor may be any one of, or a combination of, a computer, a microprocessor, a CPU, an ASIC, and electronic circuitry or logic circuits.

The processor may be electrically connected to a memory, and the processor may read data from and write data to the memory. The memory and the processor may be integrated into a single unit, or may be physically separated from each other.

Hereinafter, embodiments of the present disclosure will be described in detail with reference to the accompanying drawings.

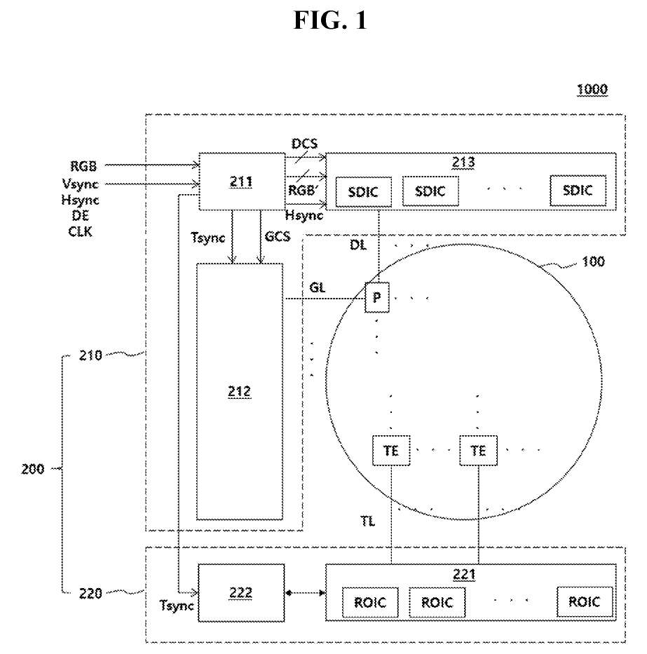

FIG. 1 is a diagram illustrating a configuration of a circular display touch device according to an embodiment of the present disclosure.

Referring to FIG. 1, a touch device 1000 of a circular display according to the embodiment of the present disclosure includes a circular touch display panel 100 and a touch display driving device 200.

The display device 1000 performs a display function and a touch sensing function, and may be implemented as a flat panel display such as a liquid crystal display (LCD) or an organic light emitting diode (OLED) display.

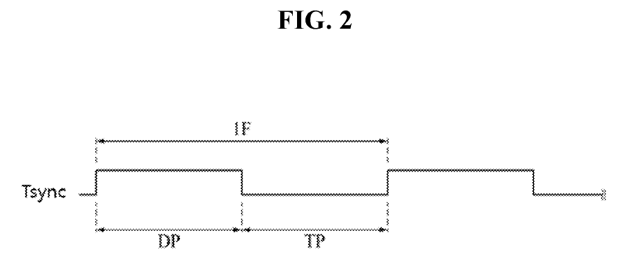

As illustrated in FIG. 2, the circular touch display panel 100 may be driven in a display period DP and a touch sensing period TP. The circular touch display panel 100 displays an image during the display period DP and functions as a touch panel for touch sensing during the touch sensing period TP.

The touch display panel may have various shapes such as a rectangular shape or a circular shape. In an embodiment of the present disclosure, the touch display panel may have a circular shape. The circular touch display panel 100 displays an image of a predetermined gray level or receives a touch input. The circular touch display panel 100 may be an in-cell touch type display panel using a capacitive method. Alternatively, the circular touch display panel 100 may be an in-cell touch type display panel using a self-capacitance method or an in-cell touch type display panel using a mutual-capacitance method.

The circular touch display panel 100 includes a plurality of gate lines GL, a plurality of data lines DL, a plurality of pixels P, a plurality of touch sensors TE, and a plurality of touch lines TL.

Each of the plurality of gate lines GL receives a scan pulse during the display period DP. Each of the plurality of data lines DL receives a data signal during the display period DP. The plurality of gate lines GL and the plurality of data lines DL are disposed to cross each other on a substrate to define a plurality of pixel regions. Each of the plurality of pixels P may include a thin film transistor (not illustrated) connected to adjacent gate lines and data lines, a pixel electrode (not illustrated) connected to the thin film transistor, and a storage capacitor (not illustrated) connected to the pixel electrode.

Each of the plurality of touch sensors TE may function as a touch electrode for sensing touch, or may function as a common electrode that forms an electric field together with the pixel electrode to drive liquid crystals. That is, each of the plurality of touch sensors TE may be used as the touch electrode during the touch sensing period TP and may be used as the common electrode during the display period DP. Accordingly, each of the plurality of touch sensors TE may include a transparent conductive material.

Each of the plurality of touch sensors TE is used as a self-capacitance type touch sensor during the touch sensing period TP, and thus needs to have a size larger than a minimum contact size between a touch object and the circular touch display panel 100. Accordingly, each of the plurality of touch sensors TE may have a size corresponding to one or more pixels P. The plurality of touch sensors TE may be arranged at regular intervals along a plurality of horizontal lines and a plurality of vertical lines. During the display period DP, each of a plurality of touch lines T1 to Tk supplies a common voltage to a corresponding touch sensor TE. Each of the plurality of touch lines T1 to Tk is individually connected to each of the plurality of touch sensors TE.

The touch display driving device 200 supplies data signals to the plurality of pixels P included in the circular touch display panel 100 during the display period DP so that an image is displayed through the circular touch display panel 100, and senses a touch through the touch sensors TE.

The touch display driving device 200 includes a display driving device 210 and a touch sensing device 220.

The display driving device 210 supplies data signals to the plurality of pixels P included in the circular touch display panel 100 during the display period DP so that an image is displayed through the circular touch display panel 100.

The display driving device 210 includes a timing controller 211, a gate driving device 212, and a data driving device 213.

The timing controller 211 receives various timing signals including a vertical synchronization signal Vsync, a horizontal synchronization signal Hsync, a data enable signal DE, and a clock signal CLK from an external system (not illustrated), and generates a gate control signal GCS for controlling the gate driving device 212 and a data control signal DCS for controlling the data driving device 213. In addition, the timing controller 211 receives a first image signal RGB from the external system, converts the first image signal RGB into a second image signal RGB′ in a form processable by the data driving device 213, and outputs the converted signal.

Meanwhile, the timing controller 211 may compress an external data enable signal transmitted from a host system within a preset display period DP to generate an internal data enable signal iDE. As illustrated in FIG. 2, the timing controller 211 may generate a touch synchronization signal Tsync that time-divisionally divides one frame period 1F into the display period DP and the touch sensing period TP in accordance with the timing of the vertical synchronization signal Vsync and the internal data enable signal. The timing controller 211 may transmit the touch synchronization signal Tsync to the gate driving device 212, the data driving device 213, a touch driving device 221, and a touch controller 222.

The host system converts digital image data into a format suitable for displaying the data on the circular touch display panel 100. The host system transmits the digital image data together with timing signals to the timing controller 211. The host system is implemented as any one of a television system, a set-top box, a navigation system, a DVD player, a Blu-ray player, a personal computer (PC), a home theater system, or a phone system, and receives an input image.

Meanwhile, the host system may receive touch input coordinates from the touch controller 222 and execute an application program associated with the received touch input coordinates.

Referring again to FIG. 1, the gate driving device 212 receives the gate control signal GCS from the timing controller 211 during the display period DP. The gate control signal GCS may include a gate start pulse GSP, a gate shift clock GSC, and a gate output enable signal GOE. The gate driving device 212 generates gate pulses (or scan pulses) synchronized with data signals based on the received gate control signal GCS, and shifts the generated gate pulses to sequentially supply the gate pulses to the gate lines GL. To this end, the gate driving device 212 may include a plurality of gate drive ICs (not illustrated). The gate drive ICs sequentially supply gate pulses synchronized with the data signals to the gate lines GL under the control of the timing controller 211 during the display period DP, thereby selecting data lines to which the data signals are written. The gate pulses swing between a gate high voltage and a gate low voltage.

The gate driving device 212 may supply a gate low voltage VGL to the gate lines GL without generating gate pulses during the touch sensing period TP. Accordingly, during the display period DP, the gate lines GL supply gate pulses to thin film transistors (TFT) of respective pixels to sequentially select data lines to which data signals are written in the circular touch display panel 100, and during the touch sensing period TP, the gate lines GL maintain the gate low voltage to prevent variations in outputs of the touch sensors.

The data driving device 213 receives the data control signal DCS and the second image signal RGB′ from the timing controller 211 during the display period DP. The data control signal DCS may include a source start pulse SSP, a source sampling clock SSC, and a source output enable signal SOE. The source start pulse controls a data sampling start timing of n source drive ICs (not illustrated) included in the data driving device 213. The source sampling clock is a clock signal that controls a data sampling timing in each of the source drive ICs. The source output enable signal controls an output timing of each source drive IC.

The data driving device 213 converts the received second image signal RGB′ into an analog data signal and supplies the analog data signal to the pixels P through the plurality of data lines DL.

The touch sensing device 220 senses a touch through the touch sensors TE during the touch sensing period TP. Specifically, the touch sensing device 220 supplies a touch driving signal to the touch sensors TE to drive the touch sensors TE, and senses a change in capacitance generated when a touch occurs on the touch sensors TE.

When the circular touch display panel 100 is implemented as a mutual-capacitance type panel, a read-out integrated circuit ROIC may include a driving circuit that generates a touch driving signal for driving the touch sensors TE and supplies the touch driving signal to the touch sensors TE through the touch lines T1 to Tk, and a sensing circuit that senses a change in capacitance of the touch sensors TE through the touch lines T1 to Tk to generate touch sensing data.

Alternatively, when the circular touch display panel 100 is implemented as a self-capacitance type panel, the read-out integrated circuit ROIC may use a single circuit to supply a touch driving signal to the touch sensors TE and to obtain touch sensing data from the touch sensors TE.

Referring again to FIG. 1, the touch sensing device 220 includes the touch driving device 221 and the touch controller 222.

The touch driving device 221 drives the touch sensors TE during the touch sensing period TP to receive touch sensing data from the touch sensors TE.

The touch driving device 221 may include a plurality of read-out integrated circuits ROIC.

The read-out integrated circuits ROIC supply a common voltage Vcom to the touch sensors TE through the touch lines TL during the display period DP. Accordingly, the touch sensors TE function as common electrodes during the display period DP.

Further, in the above-described embodiment, even though a source drive integrated circuit SDIC and the read-out integrated circuit ROIC are illustrated as being implemented as separate components, the source drive integrated circuit SDIC and the read-out integrated circuit ROIC may be implemented in an integrated form on a single chip.

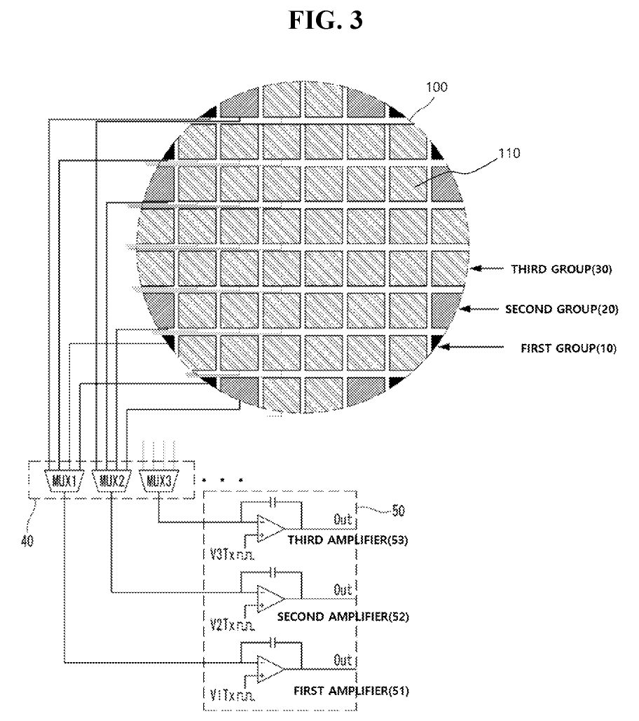

FIG. 3 is a diagram illustrating a configuration in which touch sensor nodes are grouped based on sizes in a circular touch display panel according to an embodiment of the present disclosure.

Referring to FIG. 3, the circular touch display panel 100 includes a first group 10, a second group 20, and a third group 30 obtained by classifying a plurality of touch sensor nodes 110 based on sizes, and includes a plurality of multiplexers 40 and a plurality of amplifiers 50 for independently processing touch signals for each group.

In the present disclosure, the “size” of a touch sensor node refers to a physical dimension of the touch sensor node. For example, the size of the touch sensor node may include at least one of an area, a width, a length, or a combination thereof, as defined by a geometric shape of the touch sensor node disposed on the touch display panel.

In addition, the size of the touch sensor node may be associated with an electrical characteristic corresponding to the physical dimension of the touch sensor node. For example, the electrical characteristic may include a baseline capacitance, an effective sensing capacitance, or a capacitance change range of the touch sensor node. Accordingly, touch sensor nodes having different sizes may exhibit different signal-to-noise ratio (SNR) characteristics during touch sensing.

In the present disclosure, classification of the touch sensor nodes into a plurality of node groups may be performed based on the physical sizes of the touch sensor nodes and/or the electrical characteristics corresponding to the physical sizes. Touch signals generated from the touch sensor nodes are processed according to the node groups to which the touch sensor nodes belong.

In the circular touch display panel 100, sizes of touch sensors in a central region are relatively uniform, but sizes of sensor nodes decrease as a distance from an outer region decreases, which may reduce touch sensitivity. In small sensor nodes (the first group 10), an amount of change in capacitance decreases, which may make signal detection difficult.

The circular touch display panel 100 may be classified into a plurality of groups, such as a first group 10, a second group 20, and a third group 30, in which touch sensor nodes have different sizes. By classifying touch sensor nodes having similar sizes as a group and touch driving voltage levels are allowed to be adjusted for each group, uniform touch sensitivity may be maintained. In an embodiment of the present disclosure, the touch sensor node sizes may be defined in the order of the first group 10 < the second group 20 < the third group 30. Further, in an embodiment of the present disclosure, the circular touch display panel 100 is divided into three groups according to the touch sensor node size, but the present disclosure is not limited thereto.

The touch sensor node 110 refers to a minimum unit that individually senses capacitance in the circular touch display panel 100, and by using a capacitance-based touch sensing method (self-capacitive method), a signal change of a touch input may be detected at an individual touch node. In a circular display, since the sensor node size of the touch panel is not uniform and the sensor node size becomes smaller as a distance from the outer region of the display decreases, the present disclosure divides the touch sensor nodes into the first group 10, the second group 20, and the third group 30 according to size, and differentially adjusts the driving voltage for each group, so that uniform touch sensitivity may be maintained.

The touch sensor node 110 includes a touch electrode. The touch electrode is an electrode for transmitting and receiving signals in the touch panel, and may detect a touch event by sensing a change in capacitance. In the present disclosure, self-capacitive electrodes are arranged in individual dot form (application of a self-dot type touch sensor structure), so that signal variations according to differences in the sizes of the touch sensors may be effectively processed.

A driving voltage VTx is a driving voltage applied to induce a capacitance change in the touch sensor node 110. In an embodiment of the present disclosure, the driving voltage may be differentially adjusted according to the size of the touch sensor node 110, so that an SNR may be optimized. As the size of the touch sensor node 110 becomes smaller, the driving voltage is increased to correct touch signal sensitivity.

A reception voltage VRx is a signal generated according to a capacitance change when a touch input is detected. In an embodiment of the present disclosure, a MUX (multiplexer) 40 may be used to independently process signals generated from each touch sensor node 110 for each group.

The MUX 40 is a switching circuit that selectively transmits one of a plurality of input signals to one output. In an embodiment of the present disclosure, in a state in which the touch sensor nodes 110 are divided into the first group 10, the second group 20, and the third group 30 according to size, signals generated for each group are classified by group (MUX1, MUX2, and MUX3) through the MUX 40 and transmitted to an amplifier 50. Since the MUX 40 may enable individual processing of signals of each group of touch sensor nodes, an optimal SNR for each group may be maintained. In an embodiment of the present disclosure, the touch sensor nodes 110 may be classified according to size into a first group 10 having a first touch sensor node size, a second group 20 having a second touch sensor node size larger than the first touch sensor node size, and a third group 30 having a third touch sensor node size larger than the second touch sensor node size.

The amplifier 50 is electrically connected to the MUX 40, may amplify a difference between a signal received from the MUX 40 and the driving voltage to detect a touch signal, and may include a filtering function to minimize noise (environmental noise (EMI)).

In the amplifier 50, a first level voltage V1 is supplied to the first group 10, a second level voltage V2 lower than the first level is supplied to the second group 20, and a third level voltage V3 lower than the second level is supplied to the third group 30, so that uniform touch sensitivity may be maintained.

The amplifier 50 may primarily amplify a reception voltage VRx signal detected from the touch sensor node to perform basic signal amplification. In particular, since a signal of the first group 10 is weak, a higher amplification rate may be applied to correct sensitivity. The primarily amplified signal may be additionally amplified and processed by the touch driving device 221. In this process, low-pass filtering may be applied to remove high-frequency noise, and if necessary, adaptive filtering may be applied to minimize environmental noise (EMI). The amplified signal is transmitted to the touch driving device 221, and the touch driving device 221 may detect touch coordinates and events through signal analysis and transmit the detected information to a UI system.

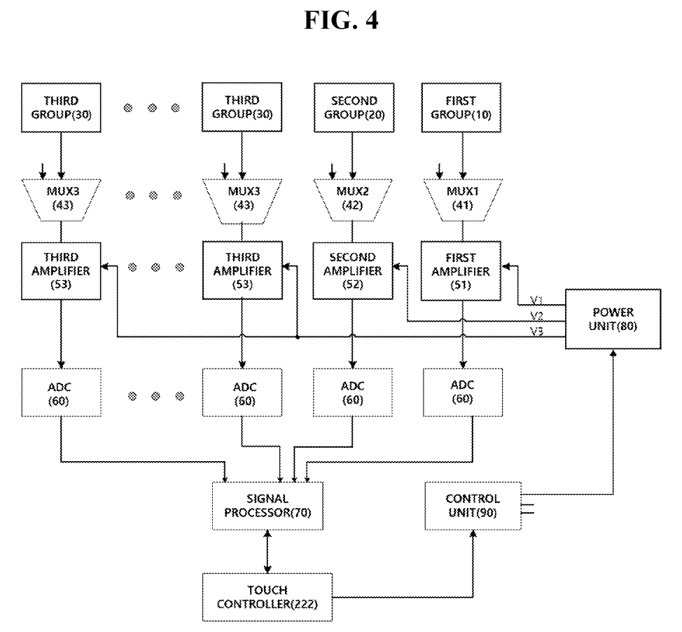

FIG. 4 is a block diagram illustrating a configuration in which touch sensor nodes are grouped based on size in the circular touch display panel according to an embodiment of the present disclosure.

Referring to FIG. 4, the circular touch display panel 100 includes the first group 10, the second group 20, and the third group 30 obtained by classifying the plurality of touch sensor nodes 110 based on size, and includes a plurality of MUXs 41 to 43, a plurality of amplifiers 51 to 53, an ADC 60, a signal processor 70, the touch controller 222, a power unit 80, and a control unit 90, for independently processing touch signals for each group.

When a touch sensor node detects a touch input, a signal is transmitted to a corresponding group (the first group 10, the second group 20, or the third group 30). Touch sensor nodes are grouped according to size, and an optimal driving voltage V1, V2, or V3 may be applied for each group.

Touch signals of each group are selectively output through the MUXs 41 to 43, which allows the touch controller 222 to process signals for each group.

Signals output from the MUXs 41 to 43 are amplified through group-specific amplifiers, namely, the first amplifier 51, the second amplifier 52, and the third amplifier 53. As the touch sensor size becomes smaller, the signal becomes weaker, and thus a group including smaller sensors may perform stronger amplification. The third group is not located in an edge area, and thus may include the largest number of touch sensor nodes, and accordingly, the number of corresponding MUX3s 43 and third amplifiers 53 may be the largest.

The amplified signal is converted into a digital signal through the ADC 60, and the touch controller 222 may accurately analyze the signal.

The signal converted by the ADC 60 is transmitted to the signal processor 70, and the signal processor 70 may perform noise removal filtering, SNR optimization, and touch coordinate calculation.

The power unit 80 transmits driving voltages V1, V2, and V3 to the first amplifier 51, the second amplifier 52, and the third amplifier 53, respectively, to achieve supply for each touch sensor group, so that it is possible to prevent a reduction in touch sensor sensitivity in the edge area and maintain optimized SNR.

Based on the data analyzed by the signal processor 70, the touch controller 222 detects final touch coordinates and input event, and the detected touch event may be linked with a UI system and reflected in a user interface UI.

The control unit 90 may analyze a signal sensed at a touch sensor node based on data obtained through the touch controller 222 to determine whether current touch is in an active state or an inactive state.

When the touch is in the inactive state and a power saving mode is in an inactive state, the control unit 90 sets touch driving voltages (the first level voltage to the third level voltage) according to sizes of touch sensor node groups (the first to third groups), and transmits the set voltages to the power unit 80, so that the power unit 80 may command supply the set touch driving voltages to the plurality of amplifiers 50. When the touch is in the inactive state and the power saving mode is in the active state, the control unit 90 may reduce unnecessary power consumption by changing the first level voltage V1 and the second level voltage V2 to the third level voltage V3 and transmitting the changed voltages to the power unit 80, so that the power unit 80 may command supply the adjusted touch driving voltage to the plurality of amplifiers 50.

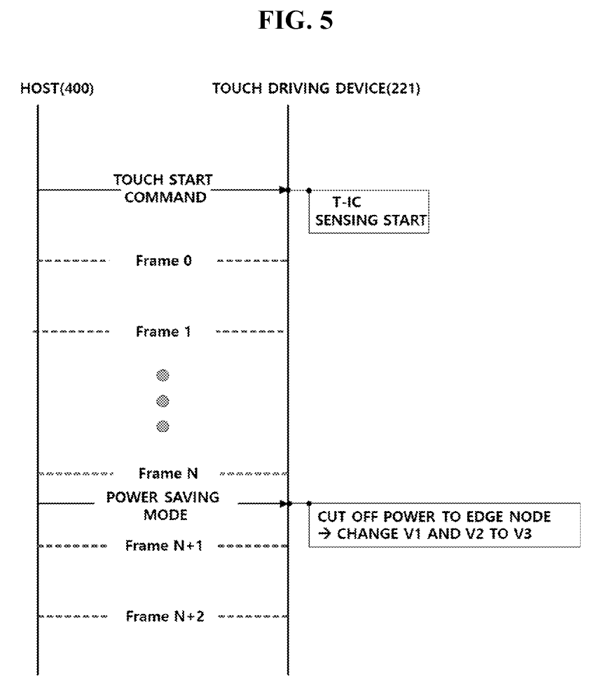

FIG. 5 is a diagram illustrating a scenario of changing a touch mode by a host in the circular touch display panel according to an embodiment of the present disclosure.

In response to the host 400 transmitting a "touch start command", the touch driving device 221 starts touch sensing. This operation may be performed by detecting touch signals over several frames, and touch sensing may be performed from Frame 0, Frame 1, …, to Frame N.

In response to the power saving mode being activated in Frame N, a process of cutting off power to edge nodes and changing the first level voltage V1 and the second level voltage V2 to the third level voltage V3 may be performed.

From Frame N+1, Frame N+2, and thereafter, operation may be maintained in the state where the voltage is changed, and the touch controller 222 may perform touch sensing while maintaining the changed voltage.

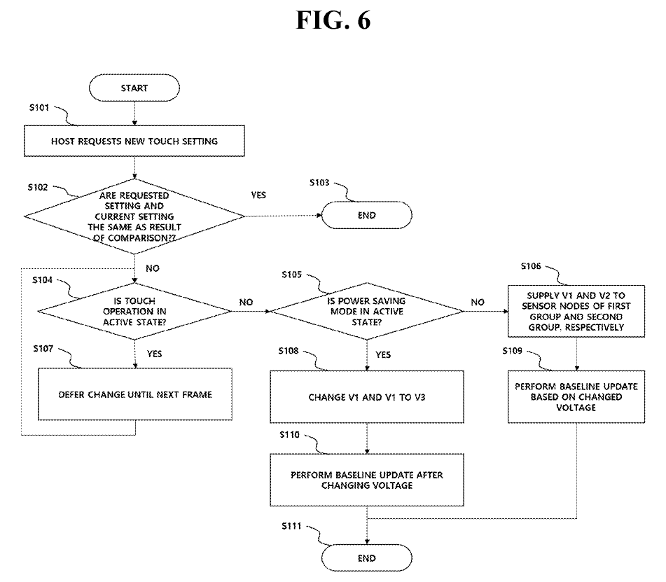

FIG. 6 is a flowchart in which the power unit is controlled by the touch driving device of the circular touch display panel according to an embodiment of the present disclosure.

In response to the host 400 requesting a new touch setting S101, the touch driving device compares a current setting with the new touch setting requested by the host 400 to determine whether a change is required S102. When the settings are the same (Yes of S102), the operation is terminated (S103). When the settings are not the same (No of S102), it is verified whether the touch is in the active state (S104). Here, the "touch is in the active state" refers to a state in which the touch sensor is currently detecting a touch input, that is, a state in which the user is touching the display or a touch signal is activated.

When the touch is in the active state (Yes of S104), the change is deferred until the next frame S107. When the touch is not in the active state (No of S104), it is verified whether the power saving mode is in the active state (S105).

When the power saving mode is the inactive state (No of S105), the power unit 80 supplies the first level voltage V1 and the second level voltage V2 to sensor nodes of the first group 10 and the second group 20, respectively. Then, a baseline update is performed based on the changed voltages (S109). Here, the baseline update refers to correcting a reference touch signal.

When the power saving mode is in the active state (Yes of S105), the first level voltage V1 and the second level voltage V2 are changed to the third level voltage V3 (S108) to save power of edge nodes. After the voltage change, the baseline update is performed (S110).

Performing the baseline update may refer to adjusting touch sensitivity by correcting a reference touch signal for a sensor node whose voltage has been changed, and the baseline update may be performed using one of two methods.

A first method is to perform the baseline update when the touch is not in the active state, that is, to adjust a touch reference signal and correct touch sensitivity when the user is not providing a touch input. Since this method is performed in a state in which there is no touch input, the touch reference signal may be stably adjusted, and changes in touch sensitivity due to external noise EMI or voltage variation may be minimized. However, the method is performed only when there is no touch, and thus may be difficult to apply while touch sensing is in progress.

A second method is to store voltages to be applied as touch reference signals at an initial touch sensing start time (the first level voltage V1, the second level voltage V2, and the third level voltage V3) in node tune code, and to perform the baseline update using the stored node tune code when a voltage change is required. This method may omit a process of verifying whether the touch is in the active state.

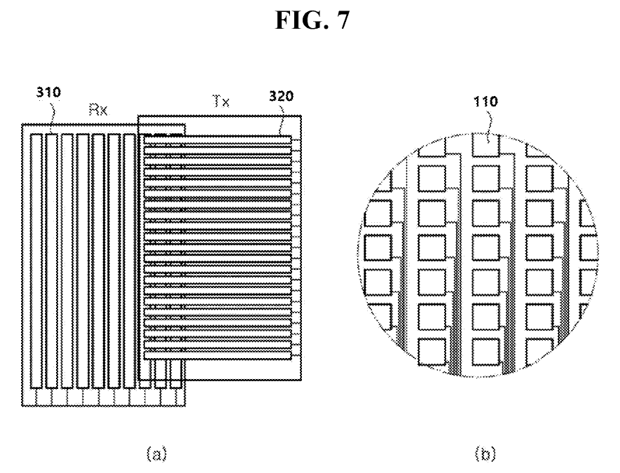

FIG. 7 is a diagram illustrating a self-dot type touch sensor (b) according to an embodiment of the present disclosure, and illustrates a mutual type touch sensor (a) for comparison.

The self-dot type touch sensor (b) according to the embodiment of the present disclosure determines whether a touch has occurred by using voltage change according to whether touch capacitance is generated at each touch sensor. That is, touch sensor electrodes are arranged in individual dot shapes rather than in continuous strip shapes as in the mutual type touch sensor (a). In particular, to adjust signal sensitivity of small touch sensor nodes in a circular display, it may be more effective to use dot shapes since driving voltages need to be individually adjustable.

The method according to the above-described embodiments may be produced as a program to be executed on a computer. The program may be stored in a computer-readable recording medium, and examples of the computer-readable recording medium include a ROM, a RAM, a CD-ROM, a magnetic tape, a floppy disk, an optical data storage device, etc., and also include implementation in the form of a carrier wave (for example, transmission via the Internet).

The computer-readable recording medium may be distributed in computer systems connected via a network, and computer-readable code may be stored and executed in a distributed manner. In addition, functional programs, code, and code segments for implementing the above-described method may be readily inferred by programmers having ordinary skill in the technical field to which the embodiments pertain.

According to at least one embodiment of the present disclosure, by providing technology that effectively improves a problem of degradation in SNR of small touch sensor nodes occurring in an outer region of a circular display, uniform touch sensitivity may be ensured over an entire display area.

According to at least one embodiment of the present disclosure, limitations of conventional touch technologies in circular displays are overcome, and touch sensitivity is uniformly maintained, so that touch performance may be optimized in various application products such as smartwatches, in-vehicle displays, and wearable devices.

Effects obtainable from the present disclosure are not limited to the effects described above, and other effects not mentioned herein may be clearly understood by those having ordinary skill in the technical field to which the present disclosure pertains from the above description.

It is apparent to those skilled in the art that the present disclosure may be embodied in other specific forms without departing from the spirit and essential characteristics of the present disclosure.

Accordingly, the above detailed description should not be construed as being restrictive in all respects but as being illustrative. The scope of the present disclosure should be determined by a reasonable interpretation of the appended claims, and all changes within the equivalent scope of the present disclosure are included in the scope of the present disclosure.

What is claimed is:

1. A touch device of a display, the touch device comprising:
a plurality of touch sensor nodes configured to sense touch signals of a touch display panel; and
a plurality of multiplexers MUXs configured to collect the touch signals sensed by the plurality of touch sensor nodes and to selectively output the touch signals, wherein:
the plurality of touch sensor nodes is classified into a plurality of node groups based on sizes of the touch sensor nodes, and
the plurality of MUXs respectively correspond to the plurality of classified node groups to collect the touch signals and selectively output at least one touch signal among the touch sensor nodes in each node group.

2. The touch device according to claim 1, wherein the plurality of touch sensor nodes includes self-dot type touch sensors.

3. The touch device according to claim 1, wherein the plurality of node groups includes a first group having a first touch sensor node size, a second group having a second touch sensor node size larger than the first touch sensor node size, and a third group having a third touch sensor node size larger than the second touch sensor node size.

4. The touch device according to claim 3, further comprising a plurality of amplifiers respectively corresponding to the plurality of MUXs and configured to amplify a difference between the touch signals output from the plurality of MUXs and a touch driving voltage.

5. The touch device according to claim 4, further comprising a power unit configured to supply the touch driving voltage to the amplifiers.

6. The touch device according to claim 5, wherein the power unit supplies the touch driving voltage having a different voltage level for each of the plurality of node groups.

7. The touch device according to claim 5, further comprising a control unit configured to control the power unit to adjust the touch driving voltage.

8. The touch device according to claim 6, wherein the supplying the touch driving voltage having a different voltage level for each of the plurality of node groups comprises supplying a first level voltage to the first group, supplying a second level voltage lower than the first level voltage to the second group, and supplying a third level voltage lower than the second level voltage to the third group.

9. The touch device according to claim 8, wherein, in a power saving mode, the first level voltage and the second level voltage are changed to the third level voltage.

10. A method for controlling a touch device of a display, the method comprising:
sensing touch signals of a touch panel; and
collecting and selectively outputting the sensed touch signals, wherein:
the sensing touch signals comprises classifying the touch signals into a plurality of groups and sensing the touch signals based on sizes of a plurality of touch sensor nodes, and
the collecting and selectively outputting the touch signals comprises collecting the touch signals respectively corresponding to the plurality of classified node groups and selectively outputting at least one touch signal among the touch sensor nodes within each node group.

11. The method according to claim 10, wherein the plurality of node groups includes a first group having a first touch sensor node size, a second group having a second touch sensor node size larger than the first touch sensor node size, and a third group having a third touch sensor node size larger than the second touch sensor node size.

12. The method according to claim 11, further comprising amplifying a difference between the output touch signal and a touch driving voltage.

13. The method according to claim 12, further comprising supplying the touch driving voltage having a different voltage level for each of the plurality of node groups.

14. The method according to claim 13, wherein the supplying the touch driving voltage having a different voltage level for each of the plurality of node groups comprises supplying a first level voltage to the first group, supplying a second level voltage lower than the first level voltage to the second group, and supplying a third level voltage lower than the second level voltage to the third group.

15. The method according to claim 14, wherein, in a power saving mode, the first level voltage and the second level voltage are changed to the third level voltage.
